(19) United States
(12) Patent Application Publication
(10) Pub. No.: US 2002/0137360 A1
(43) Pub. Date: Sep. 26, 2002

(54) Method for stabilizing low dielectric constant layer

(76) Inventors: Cheng-Yuan Tsai, Yun-Lin (TW); Ming-Sheng Yang, Hsin-Chu City (TW)

Correspondence Address: POWELL, GOLDSTEIN, FRAZER & MURPHY LLP, P.O. BOX 97223, WASHINGTON, DC, 20090-7223, US

(21) Appl. No.: 09/814,410

(22) Filed: Mar. 22, 2001

(51) Int. Cl. H01L 21/31; H01L 21/469; H01L 21/324; H01L 21/42

(52) U.S. Cl. 438/782; 438/778; 438/780; 438/781; 438/798

(57) ABSTRACT

The present invention provides a method for forming low dielectric constant layer in a semiconductor device comprising providing the semiconductor device. A polymer layer is formed on the semiconductor device, which has unsaturated carbon bonds compounds left after curing step. The polymer layer is then treated with ammonia-contained gas. The purpose of treatment of ammonia gas is to form and stabilize the polymer layer by saturating the unsaturated carbon bonds compounds in the polymer layer.

### BACKGROUND OF THE INVENTION

1. Field of the Invention

The invention relates to a method for stabilizing a low dielectric constant layer, and more particularly to a method for stabilizing a low dielectric constant layer by ammonia plasma treatment.

2. Description of the Prior Art

It is the nature of semiconductor physics that as the feature sizes are scaled down, the performance of internal devices in integrated circuits improves in a compounded fashion. That is, the device speed as well as the functional capability improves. The overall circuit speed, however, becomes more dependent upon the propagation speed of the signals along the interconnects that connect the various devices together. With the advent of very and ultra large scale integration (VLSI and ULSI) circuits, it has therefore become even more important that the metal conductors that form the interconnections between devices as well as between circuits in a semiconductor have low resistivity for high signal propagation. Copper is often preferred for its low resistivity, as well as for resistance to electromigration and stress voiding properties.

On the other hand, considerable attention has focused on the replacement of silicon dioxide with new materials, particular material having lower dielectric constants, since both capacitive delays and power consumption depend on the dielectric constant of the insulator. Accordingly, circuit performance enhancement has been sought by combining the copper conductors with low dielectric constant insulators (k less than approximately 4).

An example of a single damascene process using a low k dielectric material is depicted in FIG. 1. A spin-on polymer low dielectric constant material 142 such as aromatic hydrocarbon material, is spun on an interconnect layer 140. A hard mask 144 is deposited on the spin-on polymer low dielectric constant layer 142 after the curing of the spin-on polymer low dielectric constant layer 142.

However, these spin-on polymer materials usually contain unsaturated compounds, like carbon double or triple bonds compounds after curing step. The residue of unsaturated compounds, like carbon triple bonds (acetylene) would cause the chemical instability, and probably lead to out-gas issue and chemical reaction after etch and CMP processes.

Typically, one of quick resolutions to reduce the content of carbon triple bonds is to raise curing temperature. However, the higher curing temperature would additionally result in the degradation of dielectric behavior (K value) of polymer film and reduce the adhesion ability. In addition, the thermal cycle effect would be much enhanced at higher temperature. So, it is not favorable to raise curing temperature for reducing the content of residual carbon triple bonds.

### SUMMARY OF THE INVENTION

It is an object of the present invention to provide a method for low k material treatment. The unsaturated carbon bonds of low k material unreacted after curing step are saturated for maintaining low dielectric constant.

It is another object of the present invention to provide a method for stabilizing dielectric layer of low dielectric constant. The low k material is treated with ammonia (NH₃) plasma treatment for saturation of unexhausted unsaturated carbon bonds.

In the present invention, a method for stabilizing low dielectric constant layer in a semiconductor device comprises providing the semiconductor device. A polymer layer is formed on the semiconductor device, which has unsaturated carbon bonds compounds left after curing step. The polymer layer is then treated with ammonia-contained gas.

### BRIEF DESCRIPTION OF THE DRAWINGS

A better understanding of the invention may be derived by reading the following detailed description with reference to the accompanying drawing wherein:

FIG. 1 is a cross-sectional schematic diagram illustrating low dielectric constant layer applied on a single damascene structure in accordance with the prior art; and

FIG. 2 are cross-sectional schematic diagrams illustrating low dielectric constant applied on a single damascene structure in accordance with the present invention.

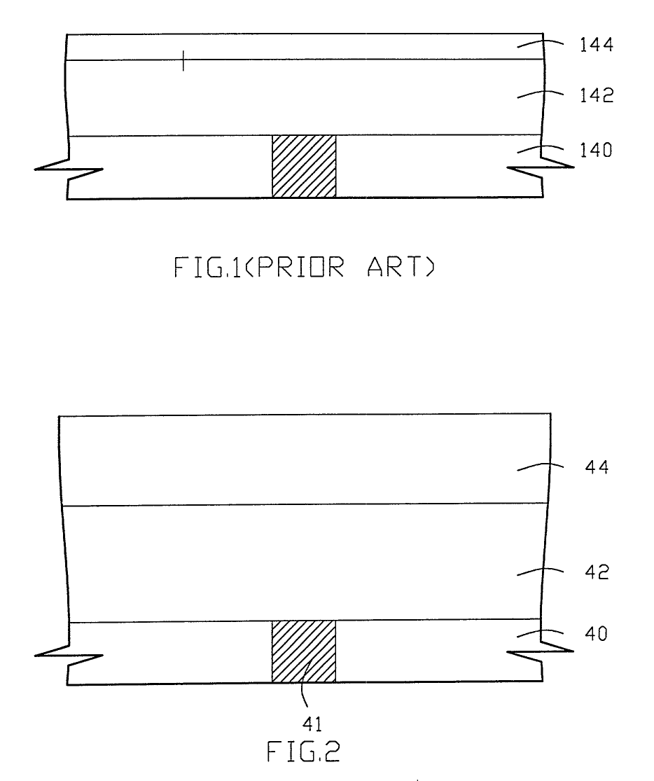

### DESCRIPTION OF THE PREFERRED EMBODIMENT

The semiconductor devices of the present invention are applicable to a board range of semiconductor devices and can be fabricated from a variety of semiconductor materials. While the invention is described in terms of a single preferred embodiment, those skilled in the art will recognize that many steps described below can be altered without departing from the spirit and scope of the invention.

Furthermore, there is shown a representative portion of a semiconductor structure of the present invention in enlarged, cross-sections of the two dimensional views at several stages of fabrication. The drawings are not necessarily to scale, as the thickness of the various layers are shown for clarify of illustration and should not be interpreted in a limiting sense. Accordingly, these regions will have dimensions, including length, width and depth, when fabricated in an actual device.

In the present invention, a method for stabilizing low dielectric constant layer in a semiconductor device comprises providing the semiconductor device. A polymer layer is spun on the semiconductor device. The polymer layer has unsaturated carbon bonds compounds. Next, the polymer layer is cured to cause cross linking of the unsaturated carbon bonds compounds. The unexhausted unsaturated carbon bonds compounds are saturated with ammonia-contained gas.

A first embodiment of the present invention is depicted in FIG. 2, which show a cross-section of an interconnect portion of a semiconductor device, such as a semiconductor structure in single damascene process. A conductor 41 having a low resistivity, such as copper, is provided in an interconnect layer 40. A low k dielectric layer 42 is then formed by spin coating, for example, low k dielectric material on the interconnect layer 40 and the conductor 41. The low k dielectric layer 42 may be made of a polymer material, such as aromatic hydrocarbon material. These materials are considered as some of the low k dielectric materials because their polymeric characteristic have dielectric constants less than about 3.

On the other hand, these materials have many unsaturated carbon bonds left, such as double or triple bonds, after forming cross-linking in curing step. First for a curing step, the low k dielectric layer 42 is spun on the interconnect layer 40 and the conductor 41 in the environment with nitrogen or argon ambient and at a temperature in the range of about 100° C. to 450° C.

Next, before the deposition of a hard mask 44 in PECVD chamber, the catalytic hydrogenation is introduced by ammonia plasma treatment. The ammonia plasma treatment contributes to the consumption and stabilization of unsaturated carbon triple bonds in the cured low k dielectric layer 42. In plasma environment, ammonia-contained gas would be ionized to be radical of hydrogen and/or nitrogen and ions/electrons, etc. These reactive radicals of hydrogen would play a major role of reduction of unsaturated carbon compounds. It should be noted that chemical etch reaction might be happened due to the environment of plasma of hydrogen and nitrogen, so that the treatment is controlled at low power and low flow of ammonia gas. However, bias power, which contributes stronger ion bombardment and etch reaction, is not applied in PECVD chamber, thus etch reaction would be minimum happened. On the other hand, during ammonia plasma treatment, an artificial bake process (degas) simultaneously happens, which would facilitate the extent of cure and further stabilize the cured polymer layer prior to the deposition of the hard mask 44. Further, the stability of film is without outgassing issue, and benefits and/or subsequent processes.

It is an object of the present invention for preventing the unexhausted unsaturated carbon bonds of the low k materials from degradation. The alkyl groups from reaction of unsaturated carbon bonds and hydrogen radicals can't raise the dielectric constant of the material.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method for stabilizing a low dielectric constant layer in a semiconductor device, said method comprising:
providing said semiconductor device;
spinning-on a polymer layer on said semiconductor device, said polymer layer comprising unsaturated carbon bonds compounds; and
treating said polymer layer with ammonia-contained gas.

2. The method according to claim 1 further comprising curing said polymer layer and having unsaturated compounds left after curing step.

3. The method according to claim 1, wherein said polymer layer comprises double carbon bonds compounds.

4. The method according to claim 1, wherein said dielectric layer comprises triple carbon bonds compounds.

5. The method according to claim 1, wherein said treating step is accomplished in a plasma environment.

6. The method according to claim 1, wherein said treating step is accomplished in a chamber of plasma enhanced chemical vapor deposition.

7. A method for stabilizing a low dielectric constant layer in a semiconductor device, said method comprising:
providing said semiconductor device;
spinning-on a polymer layer on said semiconductor device, said polymer layer having unsaturated carbon bonds compounds;
curing said polymer layer to cause cross linking of said unsaturated carbon bonds compounds; and
saturating said unexhausted unsaturated carbon bonds compounds with ammonia-contained gas.

8. The method according to claim 7, wherein said saturating step is accomplished in a plasma environment.

9. The method according to claim 7, wherein said saturating step is accomplished in plasma enhanced chemical vapor deposition chamber.

10. The method according to claim 7, wherein said saturating step is to saturate unsaturated carbon bonds with hydrogen radicals.
